(19) United States
(12) Patent Application Publication
(10) Pub. No.: US 2008/0230818 A1
(43) Pub. Date: Sep. 25, 2008

(54) NON-VOLATILE MEMORY DEVICE

(75) Inventors: Yoshinori Kumura, Yokohama-shi (JP); Tohru Ozaki, Tokyo (JP); Iwao Kunishima, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/053,137

(22) Filed: Mar. 21, 2008

(30) Foreign Application Priority Data
Mar. 23, 2007 (JP) 2007-077185

(51) Int. Cl. H01L 27/108; H01L 21/8242

(52) U.S. Cl. 257/295; 438/3; 257/E27.084; 257/E21.647; 257/E21.208

(57) ABSTRACT

According to an aspect of the present invention, there is provided a non-volatile memory including: a transistor formed on a semiconductor substrate, the transistor including: two diffusion layers and a gate therebetween; a first insulating film formed on a top and a side surfaces of the gate; a first and a second contact plugs formed on corresponding one of the diffusion layers to contact the first insulating film; a ferroelectric capacitor formed on the first contact plug and on the first insulating film, the ferroelectric capacitor including: a first and a second electrodes and a ferroelectric film therebetween; a third contact plug formed on the second electrode; and a fourth contact plug formed on the second contact plug.

### CROSS-REFERENCE TO RELATED APPLICATIONS

The entire disclosure of Japanese Patent Application No. 2007-077185 filed on Mar. 23, 2007 including specification, claims, drawings and abstract is incorporated herein by reference in its entirety.

### BACKGROUND OF THE INVENTION

1. Field of the Invention

An aspect of the present invention relates to a non-volatile memory device.

2. Description of the Related Art

In recent years, non-volatile memory devices which use ferroelectrics, such as plumbum-zirconate-titanate (PZT: P(Zr, Ti)O₃), strontium-tantalate-bismuth (SBT: SrBi₂Ta₂O₉) and the like, as a capacitive insulating film have attract public attention because of their high speed and low power consumption.

In a non-volatile memory device of a type in which a cell transistor is first formed as a switching element and a ferroelectric capacitor is formed as a storage element on the cell transistor, contact plugs are used to connect the cell transistor with the ferroelectric capacitor and to connect the cell transistor and the ferroelectric capacitor with a wiring disposed thereon through an interlayer insulating film (for example, see JP-A-2004-022824).

In the semiconductor device disclosed in JP-A-2004-022824, a contact plug for connecting a source diffusing layer of a cell transistor to a lower electrode of a ferroelectric capacitor and a lower portion of a contact plug for connecting a drain diffusing layer of the cell transistor to a wiring are formed by a photolithography method using a first mask material.

Next, an upper portion of the contact plug for connecting the drain diffusing layer of the cell transistor to the wiring and a contact plug for connecting an upper electrode of the ferroelectric capacitor to the wiring are formed by a photolithography method using a second mask material.

Thus, at least two photolithography processes are required to form the contact plugs. Since a misalignment always occurs when a plurality of photolithography processes are performed, there is a need to predict the amount of the misalignment and provide a margin in preparation for the misalignment. As a result, there arises a problem of hindrance to high integration of the non-volatile memory device.

On the other hand, there have been known semiconductor devices having a structure which is hardly affected by a misalignment (for example, see JP-A-2004-186703).

In the semiconductor device disclosed in JP-A-2004-186703, a contact plug is formed by forming a contact hole on either of source/drain regions in self-alignment with a gate electrode, depositing a conductive layer within the contact hole and on the gate electrode, and flattening the conductive layer using the gate electrode as a stopper.

However, in the semiconductor device disclosed in JP-A-2004-186703, a cell size should be increased to keep the margin for a misalignment of the contact plug formed in self-alignment with the gate electrode and the contact plug formed thereon when an aspect ratio (a ratio of height to diameter) of contact plug is increased with high integration of the non-volatile memory device

### SUMMARY OF THE INVENTION

According to an aspect of the present invention, there is provided a non-volatile memory including: a semiconductor substrate; a transistor including: a first diffusion layer that is formed in the semiconductor substrate, a second diffusion layer that is formed in the semiconductor substrate and separated from the first diffusion layer, and a gate electrode that is formed on the semiconductor substrate between the first diffusion layer and the second diffusion layer; a first insulating film that is formed on a top surface and a side surface of the gate electrode; a first contact plug that is formed on the first diffusion layer to contact the first insulating film; a second contact plug that is formed on the second diffusion layer to contact the first insulating film; a ferroelectric capacitor including: a first electrode that is formed on the first contact plug and on the first insulating film, a ferroelectric film that is formed on the first electrode, and a second electrode that is formed on the ferroelectric film; a third contact plug that is formed on the second electrode; and a fourth contact plug that is formed on the second contact plug.

According to another aspect of the present invention, there is provided a method for manufacturing a non-volatile memory, the method including: forming a transistor including a first diffusion layer, a second diffusion layer and a gate electrode with a gate insulating film on a semiconductor substrate; forming a first insulating film on a top surface and a side surfaces of the gate electrode; forming a first contact plug on the first diffusion layer to contact the first insulating film; forming a second contact plug on the second diffusion layer to contact the first insulating film; forming a ferroelectric capacitor including a first electrode on the first contact plug and on the first insulating film, a ferroelectric film on the first electrode and a second electrode on the ferroelectric film; forming a third contact plug on the second electrode; and forming a fourth contact plug on the second contact plug.

### BRIEF DESCRIPTION OF THE DRAWINGS

Embodiment may be described in detail with reference to the accompanying drawings, in which:

FIG. 1 is a block diagram showing a configuration of a non-volatile memory device according to a first embodiment;

FIG. 2 is a sectional view showing a structure of the non-volatile memory device according to the first embodiment;

FIGS. 3A to 3B are sectional views showing sequential manufacturing processes of the non-volatile memory device according to the first embodiment;

FIGS. 4A and 4B are sectional views showing sequential manufacturing processes of the non-volatile memory device according to the first embodiment;

FIGS. 5A to 5B are sectional views showing sequential manufacturing processes of the non-volatile memory device according to the first embodiment;

FIG. 6 is a sectional view showing a structure of a non-volatile memory device according to a second embodiment;

FIGS. 7A and 7B are sectional views showing sequential manufacturing processes of the non-volatile memory device according to the second embodiment;

FIG. 8 is a sectional view showing a structure of another non-volatile memory device according to the second embodiment;

FIG. 9 is a sectional view showing a structure of a non-volatile memory device according to a third embodiment;

FIGS. 10A and 10B are sectional views showing sequential manufacturing processes of the non-volatile memory device according to the third embodiment;

FIG. 11 is a sectional view showing sequential manufacturing processes of the non-volatile memory device according to the third embodiment;

FIG. 12 is a sectional view showing a structure of a non-volatile memory device according to a fourth embodiment;

FIG. 13 is a sectional view showing a structure of another non-volatile memory device according to the fourth embodiment;

FIG. 14 is a sectional view showing a structure of a non-volatile memory device according to a fifth embodiment; and

FIG. 15 is a sectional view showing a structure of another non-volatile memory device according to the fifth embodiment.

### DETAILED DESCRIPTION OF THE INVENTION

Hereinafter, exemplary embodiments will be described with reference to the accompanying drawings.

### First Embodiment

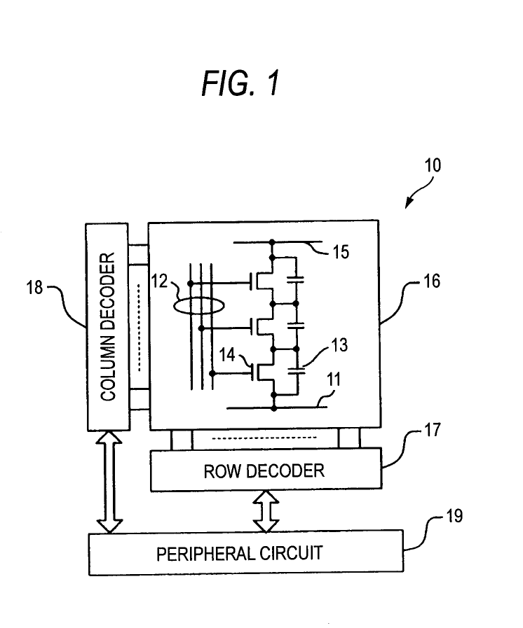

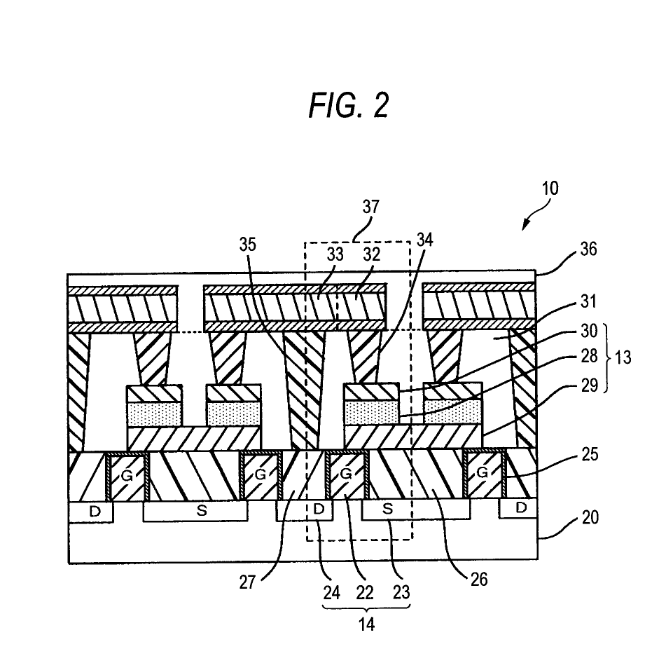

A non-volatile memory device according to a first embodiment will be described with reference to FIGS. 1 and 2. FIG. 1 is a block diagram showing a configuration of a non-volatile memory device, and FIG. 2 is a sectional view showing a structure of the non-volatile memory device.

The first embodiment shows an example of a non-volatile memory device having a so-called transistor-capacitor (TC) parallel unit-serial connection-type memory cell in which a plurality of unit cells, each of which has a cell transistor and a ferroelectric capacitor connected in parallel to each other, are symmetrically and horizontally connected in series.

As shown in FIG. 1, a non-volatile memory device 10 according to the first embodiment includes a memory cell array 16 including bit lines 11 and word lines 12 arranged in the form of a matrix; ferroelectric capacitors 13 arranged at intersections of the bit lines 11 and the word lines 12, each ferroelectric capacitor 13 having a first and a second electrodes and a ferroelectric film interposed therebetween; switching cell transistors 14 each having a drain D connected to a corresponding one of the bit lines 11, a source S connected to the first electrode of a corresponding one of the ferroelectric capacitors 13, and a gate G connected to a corresponding one of the word lines 12; and a common wire 15 connected to second electrodes of the ferroelectric capacitors 13.

In addition, the non-volatile memory device 10 includes a row decoder 17 and a column decoder 18 for selecting one of the ferroelectric capacitor 13 in the memory cell array 16; and a peripheral circuit 19 to read data out of the selected ferroelectric capacitor 13, transmit the read data to the outside, acquire data from the outside, and write the acquired data into the selected ferroelectric capacitor 13 by driving the row decoder 17 and the column decoder 18.

As shown in FIG. 2, the memory cell array 16 is formed on a semiconductor substrate 20, such as a silicon substrate.

A cell transistor 14 is formed within a region surrounded by an element isolation layer (not shown) formed on the semiconductor substrate 20.

The cell transistor 14 includes a gate electrode 22 formed on the semiconductor substrate 20 through a gate insulating film (not shown); and a source diffusing layer 23 (first diffusing layer) and a drain diffusing layer 24 (second diffusing layer) with the gate electrode 22 interposed therebetween in the gate length direction. Top and lateral sides of the gate electrode 22 are coated with a first insulating film 25.

In the embodiment, the first insulating film 25 is formed in a film shape. In the first insulating film 25, a part covering the top surface of the gate electrode 22 may be formed thicker than a part coveting the lateral surface thereof.

A first contact plug 26 is formed on the source diffusing layer 23 in self-alignment with the gate electrode 22.

A second contact plug 27 is formed on the drain diffusing layer 24 in self-alignment with the gate electrode 22.

The ferroelectric capacitor 13 includes a first electrode 29, a second electrode 30 and a ferroelectric film 28 interposed therebetween and is formed across the central portion of the gate electrode 22 from the first contact plug 26. The thickness of the ferroelectric capacitor 13 is, for example, 400 nm or so.

The first electrode 29 of the ferroelectric capacitor 13 contacts the first contact plug 26 to establish the electrical connection therebetween and is electrically isolated from the gate electrode 22 by the first insulating film 25 on the gate electrode 22.

The cell transistor 14 and the ferroelectric capacitor 13 are covered with an interlayer insulating film 31. A first wiring 32 and a second wiring 33 are formed on the interlayer insulating film 31.

A contact hole is formed in the interlayer insulating film 31, and a third contact plug 34 is disposed in the contact hole. The second electrode 30 of the ferroelectric capacitor 13 is electrically connected to the first wiring 32 through the third contact plug 34.

Another contact hole on the second contact plug 27 is formed in the inter layer insulating film 31, and a fourth contact plug 35 is disposed in the another contact hole. The drain diffusing layer 24 of the cell transistor 14 is electrically connected to the second wiring 33 through the second contact plug 27 and the fourth contact plug 35.

In this embodiment, the first wiring 32 and the second wiring 33 are provided on the interlayer insulating film 31 as a unified wiring and the third contact plug 34 is electrically connected to the fourth contact plug 35 through the unified wiring. The unified wiring of the first and the second wirings 32 and 33 are covered with an insulating film 36.

This configuration results in a unit cell 37 in which the first electrode 29 of the ferroelectric capacitor 13 is connected to the source diffusing layer 23 of the cell transistor 14 and the second electrode 30 of the ferroelectric capacitor 13 is connected to the drain diffusing layer 24.

A plurality of unit cells 37 are horizontally and symmetrically connected in series, thereby constructing the so-called TC parallel unit-serial connection-type memory cell.

In the processes of forming the first to fourth contact plugs 26, 27, 34 and 35, the first and the second contact plugs 26 and 27 are patterned in self-alignment with the gate electrode 22 and are isolated from each other by the first insulating film 25, and the third and the fourth contact plugs 34 and 35 are formed by the photolithography process. Therefore, a margin in preparation for a misalignment is not required since only one photo lithography process is performed to form the plugs.

This facilitates formation of a fine contact plug required for high integration of the non-volatile memory device 10.

A method for manufacturing the non-volatile memory device 10 will be described.

First, an STI (Shallow Trench Isolation) for element isolation (not shown) is formed on the semiconductor substrate 20 by one of methods known in the art.

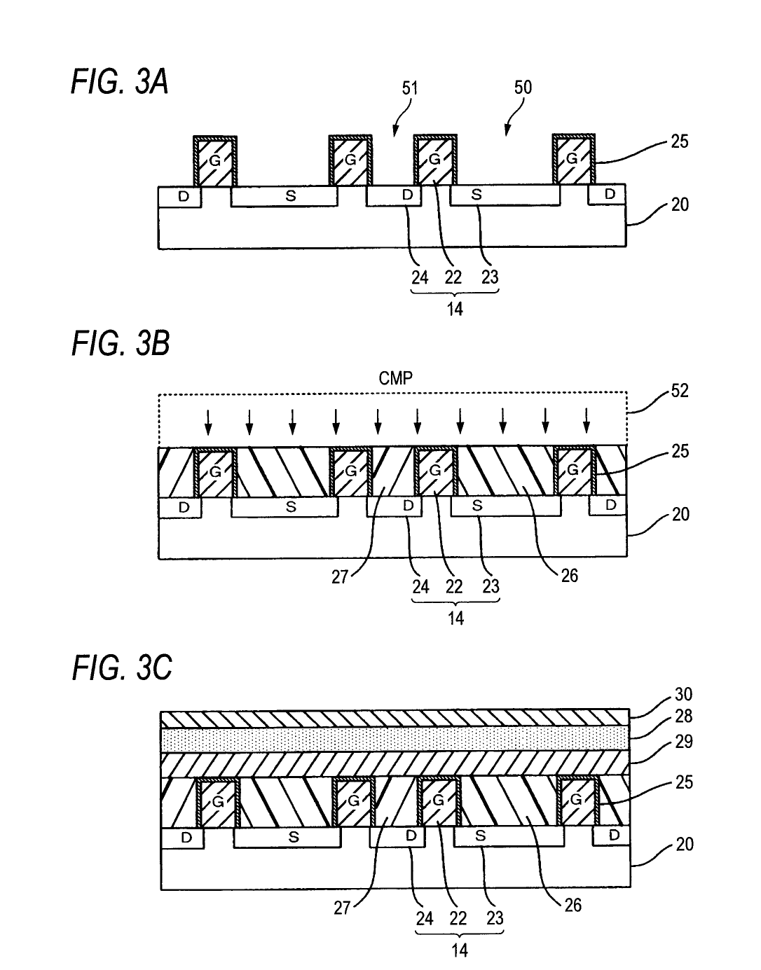

Next, as shown in FIG. 3A, the cell transistor 14 including the gate electrode 22 formed on the semiconductor substrate 20 through the gate insulating film (not shown) and the source diffusing layer 23 and the drain diffusing layer 24 with the gate electrode 22 interposed therebetween in the gate length direction is formed. The first insulating film 25 is formed on the top and the lateral sides of the gate electrode 22 by an LPCVD (Low Pressure Chemical Vapor Deposition) method. The first insulating film 25 is formed of, for example, a silicon nitride (SiN), an aluminum oxide (Al₂O₃), or the like.

Next, an interlayer insulating film (not shown), for example, a BPSG (Boron Phosphorous Silicate Glass) film, is formed on the semiconductor substrate 20, and then is flattened by removing an extra interlayer insulating film using the gate electrode 22 as a stopper by a CMP (Chemical Mechanical Polishing) method.

Next, the flattened interlayer insulating film is selectively removed, and then a contact hole 50 for forming the first contact plug 26 and a contact hole 51 for forming the second contact plug 27 are formed. The contact holes 50 and 51 are formed in self-alignment with the gate electrode 22.

The selectively remained insulating film (not shown) isolates the plurality of contact plugs each other in the depth direction on the drawing.

In the embodiment, the insulating film (not shown) is formed, flattened and selectively removed after the first insulating film 25 is formed on the top and the lateral sides of the gate electrode 22. However, the first insulating film 25 and the insulating film may be sequentially formed on the whole surface of the semiconductor substrate where the gate electrode 22 is formed, and then selectively removed.

Next, as shown in FIG. 3B, a barrier metal film (not shown), such as a TiN, is formed by a sputtering method, a metal film 52, such as a tungsten film, is formed on the semiconductor substrate 20 by a CVD (Chemical Vapor Deposition) method, and then the metal film 52 is flattened by removing an extra metal film using the gate electrode 22 as a stopper by a CMP method, thereby forming the first and the second contact plugs 26 and 27 in self-alignment with the gate electrode 22. The first and the second contact plugs 26 and 27 are formed in an inverted pattern of the gate electrode 22.

Next, as shown in FIG. 3C, the first electrode 29 having thickness of 200 nm or so, the ferroelectric film 28 having thickness of 100 nm or so, and the second electrode 30 having thickness of 100 nm or so are formed in order on the semiconductor substrate 20 by, for example, a sputtering method.

The first electrode 29 is formed of, for example, Pt, Ir, IrO₂, SRO, Ru, RuO₂, or the like.

The ferroelectric film 28 is formed of, for example, plumbum-zirconate-titanate (PZT), strontium-tantalate-bismuth (SBT), or the like.

The second electrode 30 is formed of, for example, Pt, Ir, IrO₂, SRO, Ru, RuO₂, or the like.

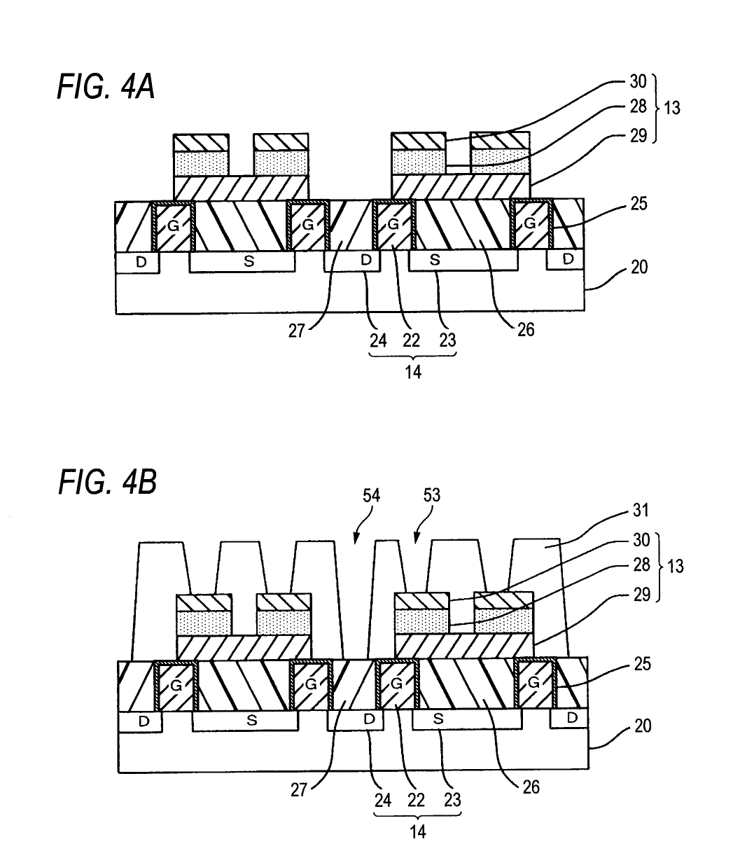

Next, as shown in FIG. 4A, the second electrode 30, the ferroelectric film 28 and the first electrode 29 are sequentially etched by an RIE (Reactive Ion Etching) method, thereby forming the ferroelectric capacitor 13 having thickness of 400 nm or so.

Next, an aluminum oxide (Al₂O₃) film is formed as a hydrogen diffusing barrier film (not shown) on the top and the lateral sides of the ferroelectric capacitor 13 by, for example, a sputtering method or an ALD (Atomic Layer Deposition) method.

Next, as shown in FIG. 4B, a TEOS (Tetra Ethyl Ortho Silicate) film is formed as an interlayer insulating film 31 on the hydrogen diffusing barrier film by, for example, a CVD method.

Next, the interlayer insulating film 31 and the hydrogen diffusing barrier film are removed using a photolithography method and an RIE method, and a contact hole 53 for forming the third contact plug 34 and a contact hole 54 for forming the fourth contact plug 35 are formed.

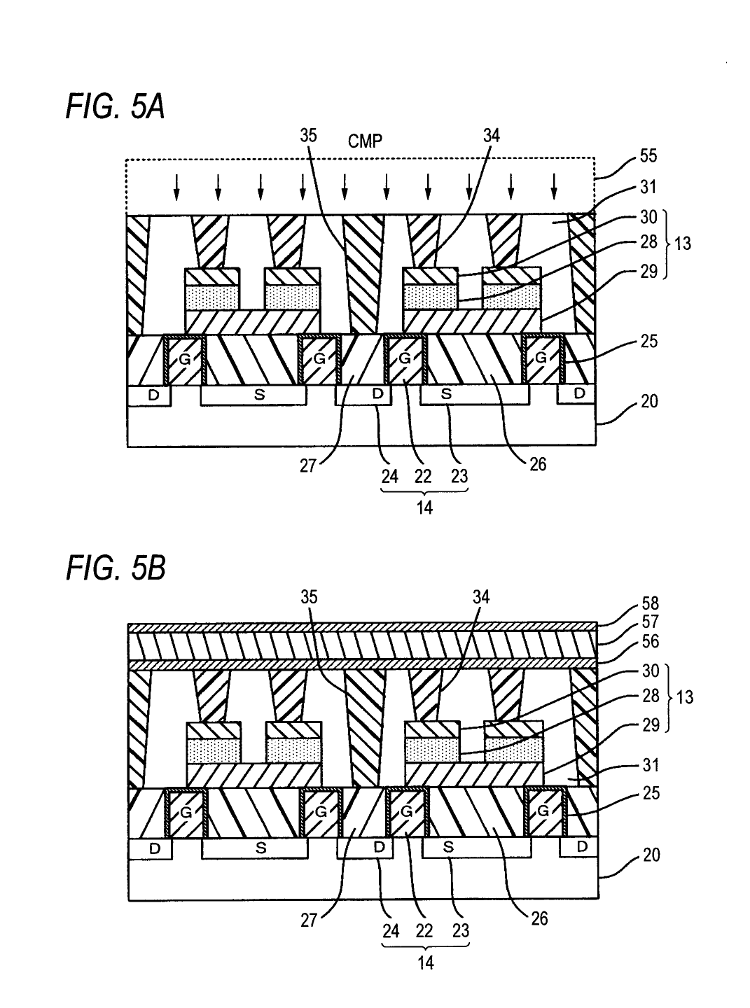

Next, as shown in FIG. 5A, a metal film 55, such as a tungsten film, is deposited on the interlayer insulating film 31 and filled in the contact holes 53 and 54 by a CVD method, and then is flattened by removing an extra metal film 55 by a CMP method using the inter layer insulating film 31 as a stopper, thereby forming the third and the fourth contact plugs 34 and 35.

Next, as shown in FIG. 5B, wiring formation materials 56, 57 and 58 are formed in order on the third contact plug 34, the fourth contact plug 35 and the interlayer insulating film 31.

The wiring formation materials 56, 57 and 58 are formed of, for example, W, Al, TiN, Cu, Ta, TaN, or the like.

Next, a unified wiring of a first wiring 32 and a second wiring 33 is formed by patterning the wiring formation materials 56, 57 and 58 according to a wiring pattern.

Next, a BPGS film is formed as an insulating film 36 on the first wiring 32, the second wiring 33 and the interlayer insulating film 31 by, for example, a CVD method, thereby covering the first wiring 32 and the second wiring 33.

Accordingly, the non-volatile memory device 10 having the TC parallel unit-serial connection-type memory cell as shown in FIG. 2 can be achieved.

In the non-volatile memory device 10 of the first embodiment, since the first and the second contact plugs 26 and 27 are formed in self-alignment with the gate electrode 22, the number of photolithography processes to form the first to fourth contact plugs 26, 27, 34 and 35 is one. Thus, there is no need to provide a margin in preparation for a misalignment caused when the plurality of photolithography processes are performed, thereby facilitating formation of a fine contact plug required for high integration of the non-volatile memory device 10.

Accordingly, it is possible to achieve the non-volatile memory device 10 which is capable of surely preventing the short-circuit between the fourth contact plug 35 over the cell transistor 14 and the first electrode 29 of the ferroelectric capacitor 13 even though the non-volatile memory device is further miniaturized.

### Second Embodiment

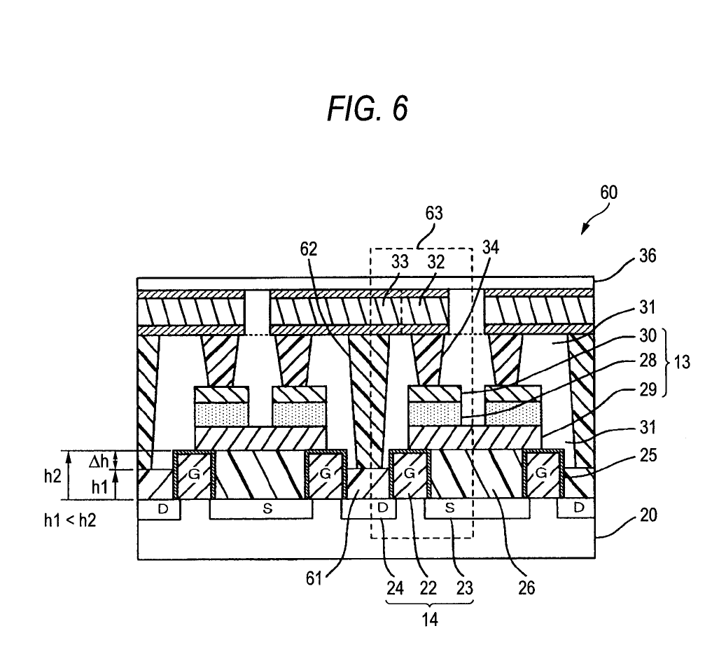

FIG. 6 is a sectional view showing a structure of a non-volatile memory device according to a second embodiment. In the second embodiment, the same elements as in the first embodiment are denoted by the same reference numerals, and explanation of which will be omitted and other elements will be described.

The second embodiment is different from the first embodiment in that the height from the drain diffusing layer to the top of the second contact plug is lower than the height from the source diffusing layer to the bottom of the first electrode.

As shown in FIG. 6, a non-volatile memory device 60 of the second embodiment includes a unit cell 63 having a second contact plug 61 such that the height h1 from the drain diffusing layer 24 to the top of the second contact plug 61 is lower by Δh than the height h2 from the source diffusing layer 23 to the bottom of the first electrode 29, and a fourth contact plug 62 contacting the second contact plug 61.

The reason why the height of the second contact plug 61 is set to be low is to prevent short-circuit between the first electrode 29 of the ferroelectric capacitor 13 and the second contact plug 61 even if patterning of the ferroelectric capacitor 13 is misaligned.

The second contact plug 61 is formed by performing a so-called pull back process, such as a CDE (Chemical Dry Etching) method, to downwardly press the top face thereof after the ferroelectric capacitor 13 as shown in FIG. 4A is formed.

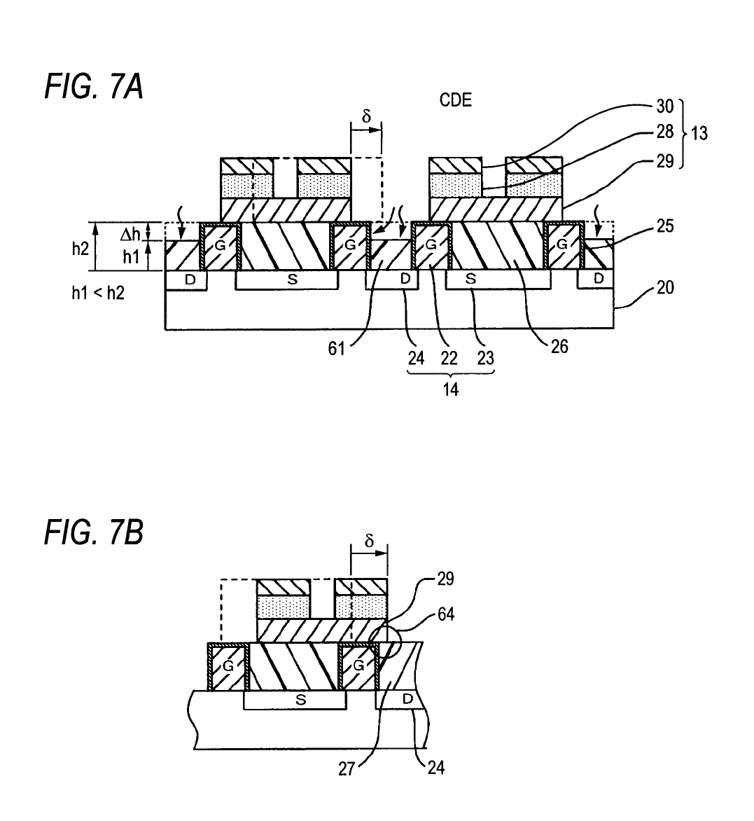

As shown in FIG. 7A, the downward pressed second contact plug 61 can be obtained by selectively etching the second contact plug 27 by Δh by the CDE method using a chlorine-based gas, such as BCl₃, Cl₂, Cl₄, or the like.

As shown in FIG. 7B, in the second contact plug 27, when a misalignment δ in the gate length direction of the ferroelectric capacitor 13 occurs, short-circuit occurs between the first electrode 29 of the ferroelectric capacitor 13 and the second contact plug 27, thereby causing hindrance to operation of the non-volatile memory device 10.

In the CDE method, which is an isotropic etching method, the second contact plug 27 immediately below the first electrode 29 in a short-circuit portion 64 is etched to disconnect the first electrode 29 from the second contact plug 27.

For example, the etching amount Δh of the second contact plug 27 is set to be small if the misalignment δ is predicted to be small and set to be large if the misalignment δ is predicted to be large.

Since the short-circuit between the first electrode 29 of the ferroelectric capacitor 13 and the second contact plug 27 caused by the misalignment δ can be repaired after the misalignment δ is occurred, it is possible to prevent the short-circuit between the first electrode 29 of the ferroelectric capacitor 13 and the second contact plug 27.

As described above, the non-volatile memory device 60 of the second embodiment has an advantage in that the short-circuit between the first electrode 29 and the second contact plug 61 is prevented, thereby increasing an effective short-margin since the height h1 from the drain diffusing layer 24 to the top of the second contact plug 61 is lower by Δh than the height h2 from the source diffusing layer 23 to the bottom of the first electrode 29.

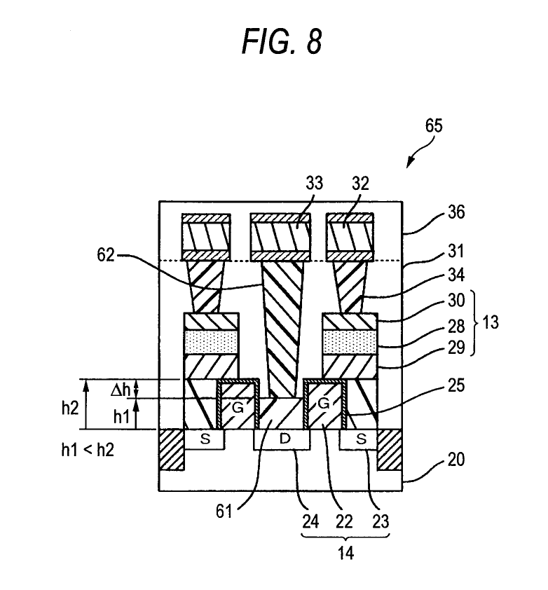

Although the non-volatile memory device 60 having the TC parallel unit-serial connection-type memory cell has been illustrated, a non-volatile memory device 65 in which the first wiring 32 is connected to the common wiring 15 and the second wiring 33 is connected to the bit lines 11 may be manufactured as shown in FIG. 8.

Although it has been illustrated that the second contact plug 27 is pressed downward after the ferroelectric capacitor 13 is formed, the second contact plug 27 may be pressed downward before the ferroelectric capacitor 13 is formed.

In this case, an RIE method, which is an anisotropic etching method, may be used as the pull back process.

Using the RIE method, the second contact plug 27 may be etched by Δh to form the second contact plug 61, an insulating film may be formed on the second contact plug 61, a surface thereof may be flattened by removing an extra insulating film by a CMP method, and then the ferroelectric capacitor 13 may be formed.

Since the etching amount Δh is sufficient if it is as high as to form the insulating film on the second contact plug 61, there is an advantage of setting the etching amount Δh irrespective of the misalignment δ of patterning of the ferroelectric capacitor 13.

Accordingly, even when the misalignment δ of patterning of the ferroelectric capacitor 13 occurs, the short-circuit between the first electrode 29 and the second contact plug 61 can be surely prevented.

### Third Embodiment

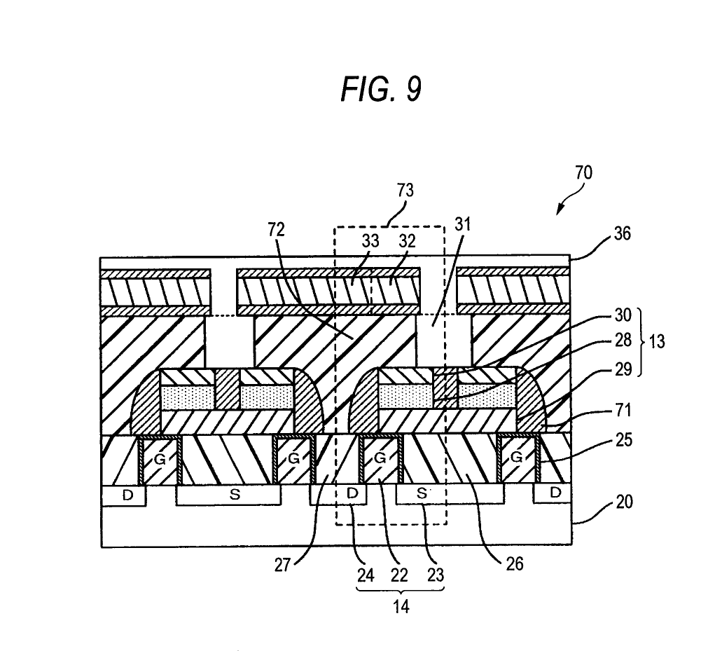

FIG. 9 is a sectional view showing a structure of a non-volatile memory device according to a third embodiment. In the third embodiment, the same elements as in the first embodiment are denoted by the same reference numerals, and explanation of which will be omitted and other elements will be described.

The third embodiment is different from the first embodiment in that the bottom of the fourth contact plug is formed in self-alignment with the ferroelectric capacitor and the third contact plug and the fourth contact plug are unified.

As shown in FIG. 9, the non-volatile memory device 70 of the third embodiment includes a unit cell 73 having a fifth T-shaped contact plug 72 contacting the second contact plug 27 and formed between a second insulating film 71 on a side wall of the ferroelectric capacitor 13 and the interlayer insulating film 31.

The fifth contact plug 72 is functioning as a unified wiring of the fourth contact plug 35 with the third contact plug 34.

The fifth contact plug 72 is formed by forming the second insulating film 71 on a side wall of the ferroelectric capacitor 13 after the ferroelectric capacitor 13 as shown in FIG. 4A is formed, forming the interlayer insulating film 31 on the cell transistor 14 and the ferroelectric capacitor 13, forming a contact hole in the interlayer insulating film 31, and filling the contact hole with a conductive material.

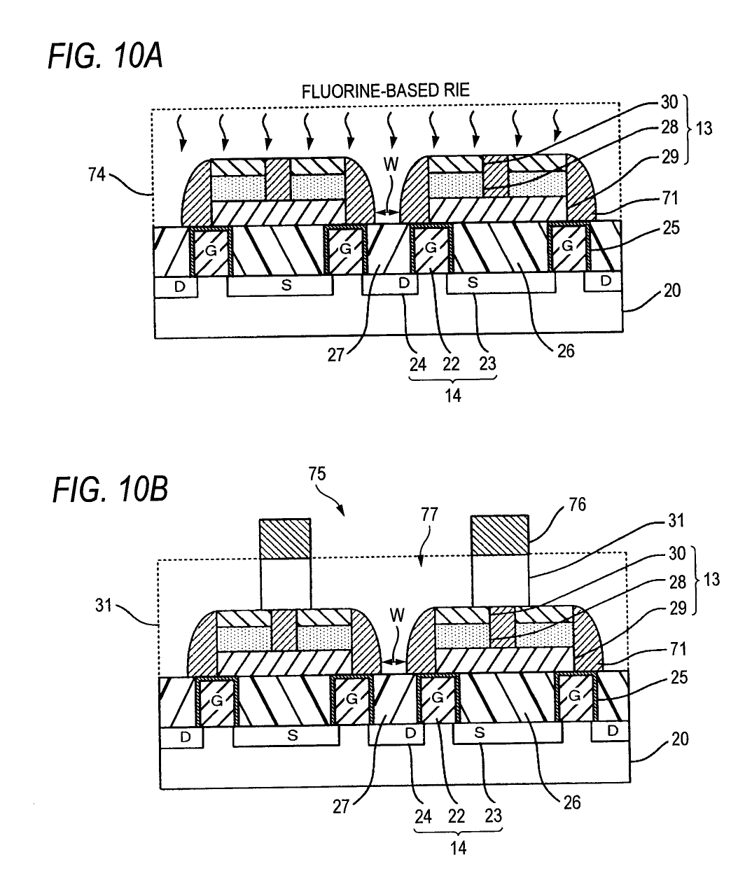

Specifically, as shown in FIG. 10A, an aluminum oxide (Al₂O₃) film 74 is formed on the cell transistor 14 and the ferroelectric capacitor 13 in, for example, a mixed gas of Argon (Ar) and oxygen (O₂) by a sputtering method.

Next, the aluminum oxide 74 is anisotropically etched by an RIE method using a fluorine-based gas so that the aluminum oxide 74 is left in the side wall of the ferroelectric capacitor 13.

Accordingly, the second insulating film 71 of the aluminum oxide is formed on the side wall of the ferroelectric capacitor 13.

Since the aluminum oxide film 74 does not pass hydrogen therethrough, the second insulating film 71 functions as a hydrogen barrier film for the ferroelectric capacitor 13.

It is possible to set a width W of a region, which is interposed between second insulating films 71 of the ferroelectric capacitor 13, as a minute size unobtainable by a lithography method (hereinafter referred to as “sub-lithographic size”).

Next, as shown in FIG. 10B, the interlayer insulating film 31 is formed on the cell transistor 14 and the ferroelectric capacitor 13.

Next, a resist film 76 having an opening 75 is formed on the inter layer insulating film 31 by a photolithography method, the interlayer insulating film 31 is etched by an RIE method using the resist film 76 as a mask, and then the second contact plug 27, the second insulating film 71 and a portion of the second electrode 30 are exposed, thereby forming a contact hole 77.

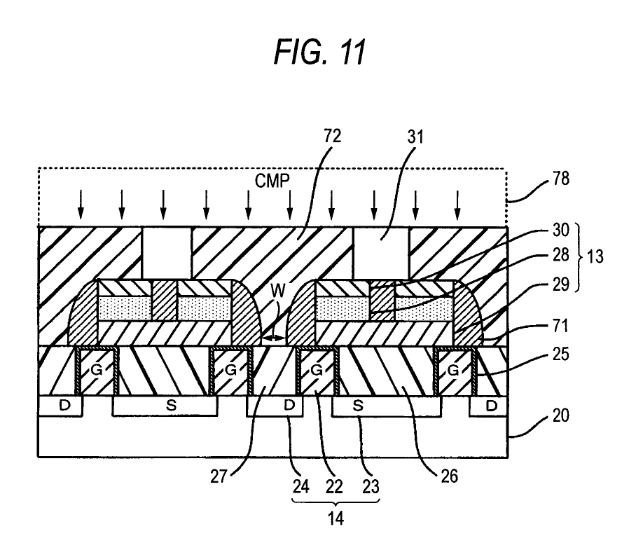

Next, as shown in FIG. 11, a metal film 78, such as a tungsten film, an aluminum film, or the like, is formed on the cell transistor 14 and the ferroelectric capacitor 13 by, for example, a CVD method or an aluminum reflow method, an extra metal film 78 is removed by a CMP method using the interlayer insulating film 31 as a stopper, and the contact hole 77 is filled with the metal film 78, thereby forming the fifth contact plug 72.

Accordingly, since the fifth contact plug 72 of a sub-lithographic size can be formed in self-alignment with the ferroelectric capacitor 13, it is possible to miniaturize the unit cell 73.

As described above, in the non-volatile memory device 70 of the third embodiment, the second insulating film 71 is formed on the side wall of the ferroelectric capacitor 13 and the fifth contact plug 72 is formed in self-alignment with the ferroelectric capacitor 13.

As a result, the fifth contact plug 72 of a sub-lithographic size can be formed, thereby enhancing the high integration of the unit cell 73.

### Fourth Embodiment

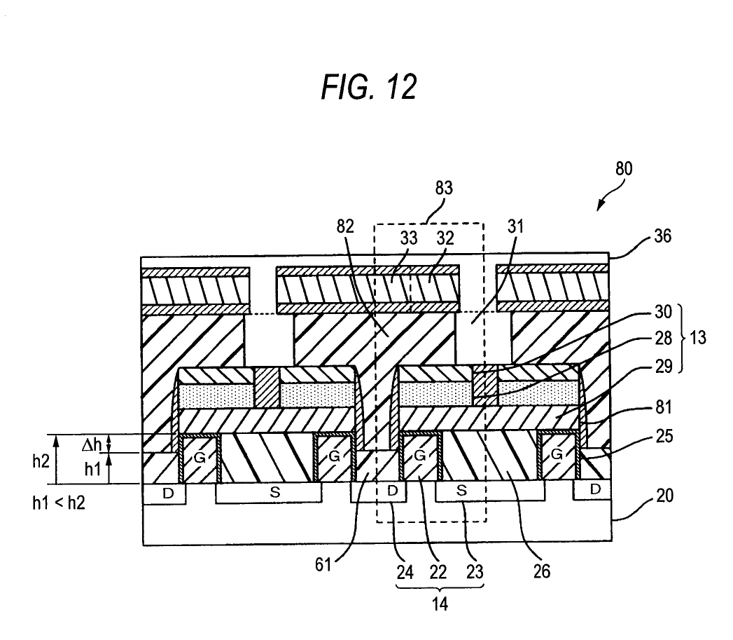

FIG. 12 is a sectional view showing a structure of a non-volatile memory device according to a fourth embodiment. In the fourth embodiment, the same elements as in the first embodiment are denoted by the same reference numerals, and explanation of which will be omitted and other elements will be described.

The fourth embodiment is different from the first embodiment in that a contact plug contacting the second contact plug in which the height from the drain diffusing layer to the top of the second contact plug is lower than the height from the source diffusing layer to the bottom of the first electrode is formed in self-alignment with the ferroelectric capacitor and the top of the gate electrode.

As shown in FIG. 12, a non-volatile memory device 80 of the fourth embodiment includes a unit cell 83 having a fifth contact plug 82 which contacts the second contact plug 61 in which the height h1 from the drain diffusing layer 24 to the top of the second contact plug 61 is lower by Δh than the height h2 from the source diffusing layer 23 to the bottom of the first electrode 29, and is formed in self-alignment with the ferroelectric capacitor 13 having a second insulating film 81 formed on its side wall and the top of the gate electrode 22.

The second insulating film 81 is formed from the side wall of the ferroelectric capacitor 13 across the top of a side wall of the gate electrode 22.

With this configuration, the short-circuit between the first electrode 29 of the ferroelectric capacitor 13 and the fifth contact plug 82 is prevented, and the short-circuit between the second contact plug 61 and the first electrode 29 due to the misalignment of patterning of the ferroelectric capacitor 13 is prevented, thereby enhancing a short-margin.

As described above, the non-volatile memory device 80 of the fourth embodiment has an advantage in that the short-circuit between the first electrode 29 of the ferroelectric capacitor 13 and the fifth contact plug 82 is prevented and the short-circuit between the second contact plug 61 and the first electrode 29 due to the misalignment δ of patterning of the ferroelectric capacitor 13 is prevented, thereby enhancing the miniaturization of the unit cell 83 since the fifth contact plug 82 is formed to contact the second contact plug 61 at a position lower by Δh than the bottom of the first electrode 29 of the ferroelectric capacitor 13 and is formed in self-alignment with the ferroelectric capacitor 13 having the second insulating film 81 formed on its side wall and the gate electrode 22.

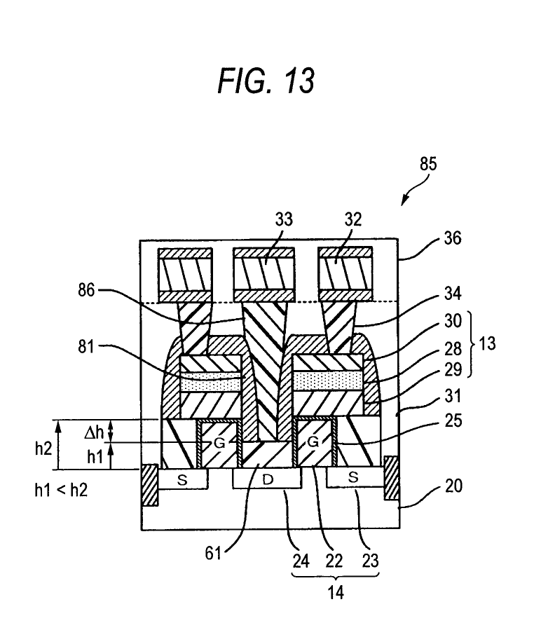

Although the non-volatile memory device 80 having the TC parallel unit-serial connection-type memory cell has been illustrated, a non-volatile memory device 85 in which the first wiring 32 is connected to the common wiring 15 and the second wiring 33 is connected to the bit lines 11 may be manufactured, as shown in FIG. 13.

In this case, a fourth contact plug 86 contacting the second contact plug 61 is formed in self-alignment with the ferroelectric capacitor 13 having the second insulating film 81 formed on its side wall and the gate electrode 22.

### Fifth Embodiment

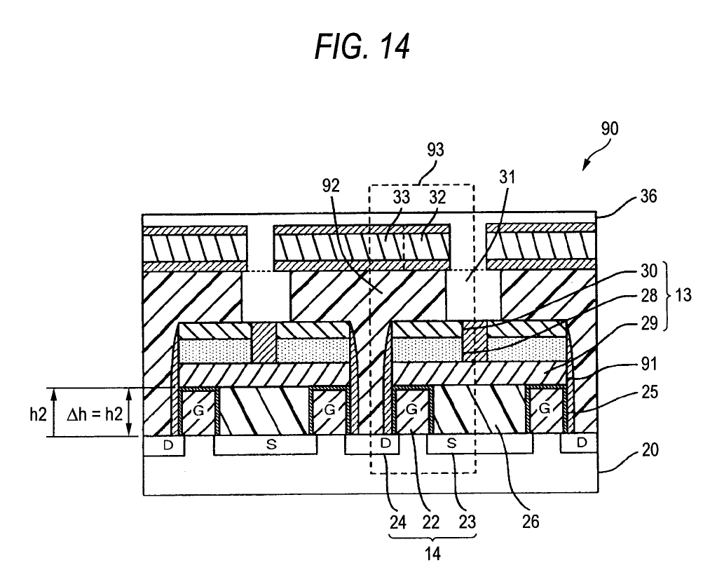

FIG. 14 is a sectional view showing a structure of a non-volatile memory device according to a fifth embodiment. In the fifth embodiment, the same elements as in the first embodiment are denoted by the same reference numerals, and explanation of which will be omitted and other elements will be described.

The fifth embodiment is different from the first embodiment in that the bottom of the fourth contact plug is formed in self-alignment with the ferroelectric capacitor, and the second to fourth contact plugs are unified.

As shown in FIG. 14, a non-volatile memory device 90 of the fifth embodiment includes a unit cell 93 having a fifth contact plug 92 which contacts the drain diffusing layer 24 and is formed in self-alignment with both of the ferroelectric capacitor 13 having a second insulating film 91 formed on its side wall and the gate electrode 22.

The second insulating film 91 is formed from the side wall of the ferroelectric capacitor 13 across the side wall of the gate electrode 22. Accordingly, the side wall of the gate electrode 22 is doubly coated by the first insulating film 25 and the second insulating film 91.

With this configuration, it is possible to reduce the pull back process for the second contact plug since the second contact plug as an individual piece is unnecessary.

As described above, the non-volatile memory device 90 of the fifth embodiment has the fifth contact plug 92 which contacts the drain diffusing layer 24 and is formed in self-alignment with both of the ferroelectric capacitor 13 having a second insulating film 91 formed on its side wall and the gate electrode 22.

As a result, there is an advantage of reduction of the pull back process for the second contact plug since the second contact plug is unnecessary.

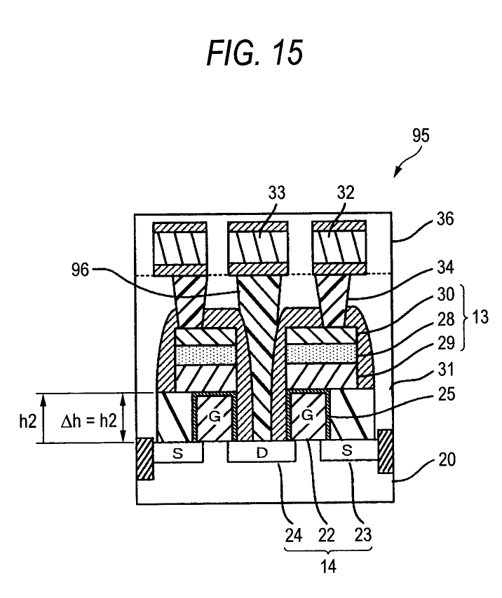

Although the non-volatile memory device 90 having the TC parallel unit-serial connection-type memory cell has been illustrated, a non-volatile memory device 95 in which the first wiring 32 is connected to the common wiring 15 and the second wiring 33 is connected to the bit lines 11 may be manufactured, as shown in FIG. 15.

In this case, a fourth contact plug 96 contacting the drain diffusing layer 24 is formed in self-alignment with both of the ferroelectric capacitor 13 having the second insulating film 91 formed on its side wall and the gate electrode 22, and the second contact plug is unified with the fourth contact plug.

According to an aspect of the present invention, there is provided a non-volatile memory device that is capable of surely preventing the short-circuit between a contact plug and a ferroelectric capacitor even though the non-volatile memory device is further miniaturized.

What is claimed is:

1. A non-volatile memory comprising:
a semiconductor substrate;
a transistor including:
a first diffusion layer that is formed in the semiconductor substrate,
a second diffusion layer that is formed in the semiconductor substrate and separated from the first diffusion layer, and
a gate electrode that is formed on the semiconductor substrate between the first diffusion layer and the second diffusion layer;
a first insulating film that is formed on a top surface and a side surface of the gate electrode;
a first contact plug that is formed on the first diffusion layer to contact the first insulating film;
a second contact plug that is formed on the second diffusion layer to contact the first insulating film;
a ferroelectric capacitor including:
a first electrode that is formed on the first contact plug and on the first insulating film,
a ferroelectric film that is formed on the first electrode, and
a second electrode that is formed on the ferroelectric film;
a third contact plug that is formed on the second electrode; and
a fourth contact plug that is formed on the second contact plug.

2. The non-volatile memory according to claim 1,
wherein a top surface of the second contact plug is lower than a top surface of the first contact plug.

3. The non-volatile memory according to claim 1 further comprising:
a second insulating film that is formed on a side surface of the ferroelectric capacitor;
wherein the fourth contact plug is formed to contact the second insulating film.

4. The non-volatile memory according to claim 3,
wherein the fourth contact plug and the third contact plug are single plug.

5. The non-volatile memory according to claim 3,
wherein the fourth contact plug, the second contact plug and the third contact plug are single plug.

6. The non-volatile memory according to claim 1 further comprising:
an interlayer insulating film that covers the transistor and the ferroelectric capacitor, the third contact plug and the fourth contact plug being formed therein;
a first wiring that is formed on the interlayer insulating film and connected with the third contact plug; and
a second wiring that is formed on the interlayer insulating film and connected with the fourth contact plug.

7. The non-volatile memory according to claim 6,
wherein the first wiring and the second wiring are a single wiring;
wherein the first electrode of the ferroelectric capacitor is electrically connected with the first diffusion layer of the transistor;
wherein the second electrode of the ferroelectric capacitor is electrically connected with the second diffusion layer of the transistor; and
wherein the ferroelectric capacitor and the transistor form a unit cell.

8. The non-volatile memory according to claim 7,
wherein the unit cell is provided with a plurality of the unit cells; and
each of the unit cells are connected in series.

9. The non-volatile memory according to claim 1,
wherein the first insulating film is formed in a film shape.

10. The non-volatile memory according to claim 1,
wherein the first insulating film includes at least one of a silicon nitride and an aluminum oxide.

11. The non-volatile memory according to claim 1,
wherein the first contact plug and the second contact plug are formed in self-alignment with the gate electrode.

12. The non-volatile memory according to claim 1,
wherein the first contact plug and the second contact plug are formed in an inverted pattern of the gate electrode.

13. A method for manufacturing a non-volatile memory, the method comprising:
forming a transistor including a first diffusion layer, a second diffusion layer and a gate electrode with a gate insulating film on a semiconductor substrate;
forming a first insulating film on a top surface and a side surfaces of the gate electrode;
forming a first contact plug on the first diffusion layer to contact the first insulating film;
forming a second contact plug on the second diffusion layer to contact the first insulating film;
forming a ferroelectric capacitor including a first electrode on the first contact plug and on the first insulating film, a ferroelectric film on the first electrode and a second electrode on the ferroelectric film;
forming a third contact plug on the second electrode; and
forming a fourth contact plug on the second contact plug.

14. The method according to claim 13 further comprising:
processing a top surface of the second contact plug to be lower than a top surface of the first contact plug.

15. The method according to claim 14,
wherein the top surface of the second contact plug is processed after the ferroelectric capacitor is formed.

16. The method according to claim 14,
wherein the top surface of the second contact plug is processed before the ferroelectric capacitor is formed.

17. The method according to claim 13 further comprising:
forming a second insulating film on a side surfaces of the ferroelectric capacitor;
wherein the fourth contact plug is formed to contact the second insulating film.

18. The method according to claim 17,
wherein the fourth contact plug and the third contact plug are formed in a single plug.

19. The method according to claim 17,
wherein the fourth contact plug, the second contact plug and the third contact plug are formed in a single plug.

20. The non-volatile memory according to claim 1,
wherein the first insulating film includes:
a first insulating film side part that is formed on the side surface of the gate electrode, and
a first insulating film top part that is formed on the top surface of the gate electrode;
wherein the first contact plug and the second contact plug contact the first insulating film side part; and
wherein the first electrode contacts the first insulating film top part.
